(19) United States
(12) Patent Application Publication
(10) Pub. No.: US 2013/0313664 A1
(43) Pub. Date: Nov. 28, 2013

(54) RESISTIVE MEMORY DEVICE AND FABRICATION METHOD THEREOF

(71) Applicants: Ha Chang JUNG, Icheon-si (KR); Jung Taik CHEONG, Icheon-si (KR)

(72) Inventors: Ha Chang JUNG, Icheon-si (KR); Jung Taik CHEONG, Icheon-si (KR)

(21) Appl. No.: 13/601,571

(22) Filed: Aug. 31, 2012

(30) Foreign Application Priority Data
May 24, 2012 (KR) 10-2012-0055453

(51) Int. Cl. H01L 29/82; H01L 21/8246

(52) U.S. Cl. 257/421; 438/3; 257/E21.665; 257/E29.323

(57) ABSTRACT

A resistive memory device capable of minimizing operation current and a fabrication method thereof are provided. The resistive memory device includes an access device, a heating electrode formed on the access device and serving as a magnetoresistance device, and a variable resistance material formed on the heating electrode.

### CROSS-REFERENCES TO RELATED APPLICATION

This application claims priority under 35 U.S.C. 119(a) to Korean application number 10-2012-0055453, filed on May 24, 2012, in the Korean Patent Office, which is incorporated by reference in its entirety.

### BACKGROUND OF THE INVENTION

1. Technical Field

The inventive concept relates to a semiconductor device, and more particularly, to a resistive memory device and a fabrication method thereof.

2. Related Art

As typical next-generation memories that replace dynamic random access memories (DRAMs) or flash memories, resistive memory devices have received attention. The resistive memory devices are memory devices using a variable resistive material of which a resistance is rapidly changed according to an applied voltage, and state is switched between at least two different resistance states.

As an example of the resistive memories, there are phase-change random access memories (PCRAMs). The PCRAM stores data by changing a crystalline state of a variable resistive material by current applied to a heating electrode.

FIG. 1 illustrates an example of a PCRAM.

Referring to FIG. 1, a PCRAM includes an access device 103 formed on a substrate 101, a heating electrode 105 formed on the access device, and a variable resistive material 107 formed on the heating electrode 105. The reference numeral 109 denotes an interlayer insulating layer, and 111 denotes an insulating layer formed on an inner circumference of the heating electrode when the heating electrode is formed in a ring shape. As the variable resistive material, a chalcogenide compound, that is, germanium-antimony-tellurium (Ge—Sb—Te, GST) may be used.

In the PCRAM, one of factors, which determine a total current consumption, is a current required to change the variable resistive material to be in a reset state, that is, a reset current. As one method of reducing a reset current, a method of reducing a contact area between the heating electrode 105 and the variable resistive material 107 is employed. Therefore, the heating electrode 105 is formed in a ring shape as shown in FIG. 1.

That is, to obtain low power consumption in the PCRAM, the contact area between the heating electrode 105 and the variable resistive material 107 has to be reduced or the variable resistive material 107 has to be formed using a metal material having high resistivity.

However, the kinds of metal materials having resistivity are limited. As the reduction rate of a device becomes increasingly day by day, minimization in a size of the heating electrode 105 is physically limited. Therefore, reduction in the reset current of the PCRAM reaches the limit.

### SUMMARY

According to one aspect of an exemplary embodiment, there is a provided a resistive memory device. The resistive memory device may include: an access device; a heating electrode formed on the access device and serving as a magnetoresistance device; and a variable resistive material formed on the heating electrode.

According to another aspect of an exemplary embodiment, there is a provided a method of fabricating a resistive memory device. The method may include: forming an access device on a substrate; forming a heating electrode on the access device; forming a variable resistance device on the heating electrode, wherein forming the heating electrode further include: forming a first ferromagnetic layer, to be magnetized in a first direction on the access device; forming a diamagnetic layer on the first ferromagnetic layer; and forming a second ferromagnetic layer, to be magnetized in direction opposite to the first direction, on the diamagnetic layer, where the second ferromagnetic layer is formed to contact the variable resistance device.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is an illustrative view of a PCRAM in the related art;

FIG. 2 is a view illustrating a configuration of a heating electrode for a resistive memory device according to an exemplary embodiment of the inventive concept;

FIG. 3 is a view illustrating a configuration of a heating electrode for a resistive memory device according to another exemplary embodiment of the inventive concept;

FIG. 4 is a view illustrating a configuration of a resistive memory device according to an exemplary embodiment of the inventive concept; and

FIG. 5 is a view illustrating a configuration of a resistive memory device according to another exemplary embodiment of the inventive concept.

### DETAILED DESCRIPTION

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

FIG. 2 is a view illustrating a configuration of a heating electrode for a resistive memory device according to an exemplary embodiment.

Referring to FIG. 2, a heating electrode 20 according to an exemplary embodiment has a stacked structure of a first ferromagnetic layer 201, a diamagnetic layer 203, and a second ferromagnetic layer 205.

The first ferromagnetic layer 201 is formed to have a spin arrangement direction, that is, a first magnetization direction. The second ferromagnetic layer 205 is formed to have a second magnetization direction opposite to the first magnetization direction. In the exemplary embodiment, the first and second ferromagnetic layers 201 and 205 may be formed of a horizontally magnetizable material.

The diamagnetic layer 203 may be formed of a metal material or an insulating material. The heating electrode 20 operates like a spin valve device when the diamagnetic layer 203 is formed of a metal material, while the heating electrode 20 operates a magnetic tunnel junction (MTJ) device when the diamagnetic layer 203 is formed of an insulating material.

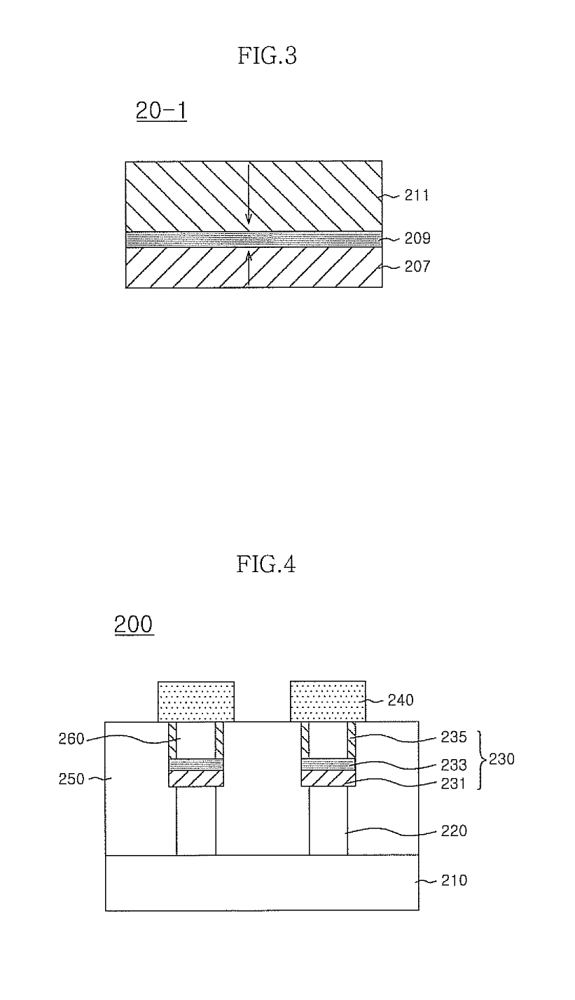

FIG. 3 is a view illustrating a configuration of a heating electrode for a resistive memory device according to another exemplary embodiment.

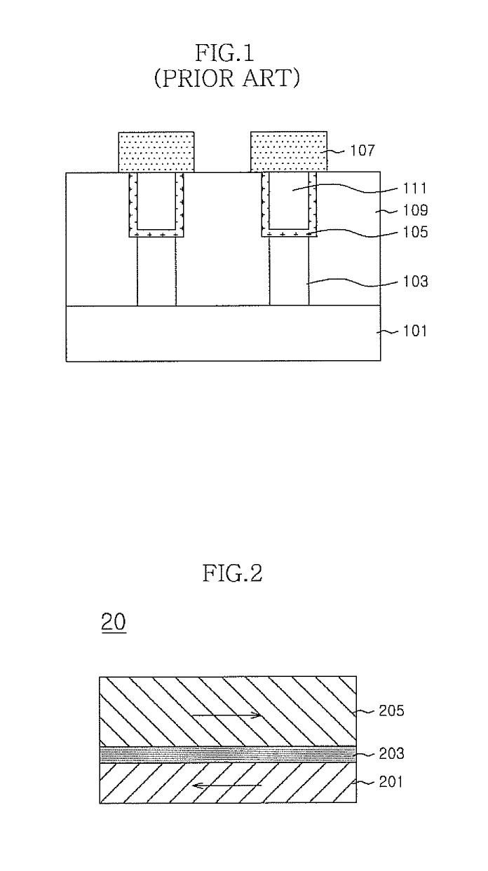

A heating electrode 20-1 according to this exemplary embodiment has a stacked structure of a first ferromagnetic layer 207, a diamagnetic layer 209, and a second ferromagnetic layer 211 like the heating electrode 20 illustrated in FIG. 1. The first and second ferromagnetic layers 207 and 211 may be formed of a vertically magnetizable material and to be magnetized in opposite directions to each other.

In the above-described exemplary embodiments, a contact area between the heating electrode 20 or 20-1 and a variable resistive material formed thereon can be increased using the first ferromagnetic layer 201 or 207 and the second ferromagnetic layer 205 or 211, which have the magnetization directions opposite to each other.

Therefore, even when not using a metal material having high resistivity, the heating electrode 20 or 20-1 having high resistance can be formed and thus a resistive memory device with low power consumption can be fabricated due to reduction in a reset current. In addition, even when the heating electrodes 20 and 20-1 are configured to have the same size as the conventional heating electrode, the contact resistance of the heating electrode with the variable resistive material can be considerably increased and thus a total current consumption can be minimized.

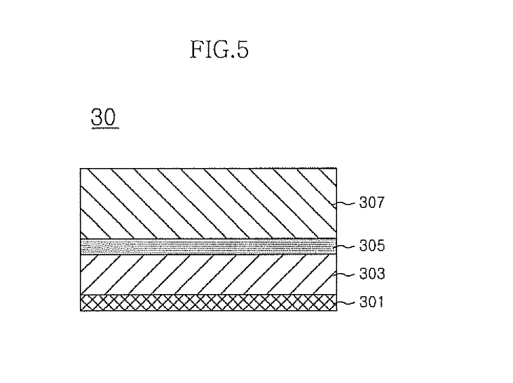

FIG. 4 is a view illustrating a configuration of a resistive memory device according to an exemplary embodiment.

Referring to FIG. 4, a resistive memory device 200 according to an exemplary embodiment includes an access device 220 formed on a substrate 210, a heating electrode 230 formed on the access device 220 and serving as a magnetoresistance device, and a variable resistive material 240 formed on the heating electrode 230. An interlayer insulating layer 250 is buried in outer circumferences of the access device 220 and the heating electrode 230.

The above-described exemplary embodiment has illustrated that the variable resistive material 240 is formed of a phase-change material which is phase-changeable through physical, chemical, electrical, or thermal energy, but it is not limited thereto. In addition, the access device 220 may be selected from various kinds of diodes (a PN diode, a shottky diode, and the like) and various kinds of transistors (a MOS transistor, an I-MOS transistor, and the like).

The heating electrode 230 may be formed in a shape which can minimize a contact area with the variable resistive material 270, for example, a ring shape. An insulating layer 260 is buried in an inner circumference of the heating electrode 230.

The shape of the heating electrode 230 is not limited to the above-described shape and various shapes such as a dash shape or a line shape may be employed as the heating electrode. The heating electrode may have any shape as long as a contact area of the heating electrode with the underlying access device 220 is sufficiently maintained and a contact area of the heating electrode with the variable resistive material 240 can be minimized.

The heating electrode 230 may include a first ferromagnetic layer 231 in contact with the access device, a diamagnetic layer 233 formed on the first ferromagnetic layer 231, and a second ferromagnetic layer 235 formed on the diamagnetic layer 233 and being in contact with the variable resistive material 240.

The first and second ferromagnetic layers may be formed so that electrons thereof are magnetized in opposite directions to each other. Further, the first and second ferromagnetic layers 231 and 235 may be selected from vertically or horizontally magnetizable materials.

For example, the first and second ferromagnetic layers 231 and 235 may be formed of a material selected from single element materials such as nickel (Ni), cobalt (co), and iron (Fe), or a multicomponent alloy containing the single element materials. The multicomponent alloy may include CoFe, CoFeB, CoNi, NiFe, CoFeSiB, FePt, NiPt, CoPt, a Heusler alloy such as CoCrFeAl, but the multicomponent alloy is not limited thereto.

The first and second ferromagnetic layers 231 and 235 may be formed by depositing a ferromagnetic material through a sputtering method in a state in which an electromagnetic field is applied to the substrate so that the magnetization direction, that is, a spin direction of electrons may be aligned in a desired direction. Alternatively, the magnetization direction may be formed by depositing the ferromagnetic material without an external magnetic field, moving the ferromagnetic material into a chamber to which an electromagnetic field is applicable, and applying a strong electromagnetic field thereof to allow the magnetization direction to be arranged.

Controlling the magnetization direction of the ferromagnetic material is deviated from the spirit of the inventive concept and thus detailed description thereof will be omitted.

A case in which data of a reset state is programmed in the variable resistive material, for example, a case in which a GST material is controlled in an amorphous state is assumed. In this case, electrons flowed from the access device 220 into the first ferromagnetic layer 231 of the heating electrode 230 is affected by a spin arrangement of the first ferromagnetic layer 231.

That is, the first ferromagnetic layer 231 magnetized in the first direction affects a spin direction of electrons moving through the first ferromagnetic layer 231. Therefore, electrons, which are magnetized in the same direction as a spin direction of the first ferromagnetic layer 231, pass through the diamagnetic layer 233 and move into the second ferromagnetic layer 235. At this time, since the second ferromagnetic layer 235 is magnetized in a direction opposite to the direction of the first ferromagnetic layer 231, spin scattering occurs to generate high electrical resistance. Therefore, the variable resistive material 240 is heated by the electrical resistance and thus a crystalline state of the GST material may be changed.

The electrical resistance is changed depending on kinds and magnetization degrees of materials for the first and second ferromagnetic layers 231 and 235 and is affected by kinds and thicknesses of materials for the diamagnetic layer 233.

As described above, the diamagnetic material 233 may be formed using a metal material so that the heating electrode 230 operates like a spin valve device. Alternatively, the diamagnetic material 233 may be formed using an insulating material so that the heating electrode operates like a MTJ device. In addition, the diamagnetic layer 233 may be formed of a metal layer, an oxide layer, or a nitride layer, which has a thickness sufficient to cause a tunneling effect, for example, a very thin thickness of several Å to several tens of Å.

Therefore, a contact resistance between the heating electrode 230 and the variable resistive material 240 can be arbitrarily controlled by controlling kinds, thicknesses, and magnetization degrees of the first and second ferromagnetic layers 231 and 235 and a thickness of the diamagnetic layer 233.

Although not shown, it is obvious in the skilled art that an upper electrode may be formed on a variable resistive material 240, or an upper electrode and a metal interconnection electrically connected to the upper electrode may be further formed on the variable resistive material 240.

FIG. 5 is a view illustrating a configuration of a resistive memory device according to another exemplary embodiment.

A heating electrode 30 according to this exemplary embodiment has a stacked structure of a fixing layer 301, a first ferromagnetic layer 303, a diamagnetic layer 305, and a second ferromagnetic layer 307.

The fixing layer 301 may be formed of an anti-ferromagnetic layer and the first and second ferromagnetic layers 303 and 307 are magnetized in opposite directions to each other.

The diamagnetic layer 305 may be formed of a material selected from the group consisting of metal materials and insulating materials.

In the heating electrode 30 according to this exemplary embodiment, a magnetization direction of the first ferromagnetic layer 303 becomes resolute by anti-ferromagnetic coupling (AFC) between the fixing layer 301 and the first ferromagnetic layer 303.

The heating electrode 30 having the above-described structure may be used as, for example, the heating electrode 230 of the resistive memory device 200 illustrated in FIG. 4.

In the resistive memory device, a case in which the reset current is adjusted depending on operation purpose may occur. In this case, a magnetization degree of the second ferromagnetic layer 307 may be changed to adjust the reset current. At this time, since large electromagnetic field is applied to the overall heating electrode 30, the magnetization direction of the first ferromagnetic layer 303 is also changed in an undesired direction.

Therefore, when the fixing layer 301 is introduced below the first ferromagnetic layer 303 and causes a spin arrangement of the first ferromagnetic layer 303 to be surely fix, only the magnetization degree of the second ferromagnetic layer 207 can be easily changed.

In the above-described exemplary embodiments, the heating electrode is formed using a material causing a magnetoresistance effect. As compared with the conventional heating electrode using a metal material, the heating electrode, which causes an electric resistance by the magnetoresistance effect, has an effect that causes large electric resistance in the same size of the heating electrode. Therefore, when the heating electrode is formed based on a reduction rate of the device, higher electrical resistance can be obtained, that is, reduction in the reset current can be reduced as compared with the conventional heating electrode. In addition, an overall operation current of the resistive memory device can minimized without using a material having high resistivity.

Further, when the heating electrode is formed of a ferromagnetic material having a high curing temperature to ensure thermal stability and thus lifespan of the resistive memory device can be extended.

Since the heating electrode is typically formed of a high resistance material such as TiN or TiAlN in the related art, diffusion from the heating electrode formed of a metal material to the variable resistive material is caused at the time of operation of the heating electrode. However, since the heating electrode is formed of a ferromagnetic material having a low diffusion coefficient, diffusion of the material constituting the heating electrode can be prevented and thus operation reliability or lifespan of the device can be remarkably improved.

Further, since the ferromagnetic material has fast quenching speed, transition of the variable resistive material to an amorphous state easily occurs and thus device characteristics can be improved.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A resistive memory device, comprising:
an access device;
a heating electrode formed on the access device and serving as a magnetoresistance device;
a variable resistive material formed on the heating electrode.

2. The resistive memory device of claim 1, wherein the heating electrode includes:
a first ferromagnetic layer magnetized in a first direction and being in contact with the access device;
a diamagnetic layer formed on the first ferromagnetic layer; and
a second ferromagnetic layer magnetized in a direction opposite to the first direction and being in contact between the diamagnetic layer and the variable resistive material.

3. The resistive memory device of claim 2, wherein the first ferromagnetic layer and the second ferromagnetic layer are magnetized in a horizontal direction.

4. The resistive memory device of claim 2, wherein the first ferromagnetic layer and the second ferromagnetic layer are magnetized in a vertical direction.

5. The resistive memory device of claim 1, wherein the heating electrode includes:
an anti-ferromagnetic layer being in contact with the access device;
a first ferromagnetic layer formed on the anti-ferromagnetic layer, the first ferromagnetic layer being magnetized in a first direction;
a diamagnetic layer formed on the first ferromagnetic layer; and
a second ferromagnetic layer being in contact between the diamagnetic layer and the variable resistive material, the second ferromagnetic layer being magnetized in a direction opposite to the first direction.

6. The resistive memory device of claim 5, wherein the first ferromagnetic layer and the second ferromagnetic layer are magnetized in a horizontal direction.

7. The resistive memory device of claim 5, wherein the first ferromagnetic layer and the second ferromagnetic layer are magnetized in a vertical direction.

8. The resistive memory device of claim 2, wherein each of the first and second ferromagnetic layers includes a single element material selected from the group consisting of nickel (Ni), cobalt (Co), and iron (Fe).

9. The resistive memory device of claim 5, wherein each of the first and second ferromagnetic layers includes a single element material selected from the group consisting of nickel (Ni), cobalt (Co), and iron (Fe).

10. The resistive memory device of claim 2, wherein each of the first and second ferromagnetic layers includes a material selected from a multicomponent alloy containing at least one of nickel (Ni), cobalt (Co), or iron (Fe).

11. The resistive memory device of claim 10, wherein the multicomponent alloy includes any one selected from the group consisting of CoFe, CoFeB, CoNi, NiFe, CoFeSiB, FePt, NiPt, CoPt, and a Heusler alloy such as CoCrFeAl.

12. The resistive memory device of claim 5, wherein each of the first and second ferromagnetic layers includes a material selected from a multicomponent alloy containing at least one of Ni, Co, and Fe.

13. The resistive memory device of claim 12, wherein the multicomponent alloy includes any one selected from the group consisting of CoFe, CoFeB, CoNi, NiFe, CoFeSiB, FePt, NiPt, CoPt, and a Heusler alloy such as CoCrFeAl.

14. The resistive memory device of claim 2, wherein the diamagnetic layer is formed of a metal material.

15. The resistive memory device of claim 5, wherein the diamagnetic layer is formed of a metal material.

16. The resistive memory device of claim 2, wherein the diamagnetic layer is formed of an insulating material.

17. The resistive memory device of claim 5, wherein the m diamagnetic layer is formed of an insulating material.

18. A method of fabricating a resistive memory device, the method comprising:
forming an access device on a substrate;
forming a heating electrode on the access device;
forming a variable resistance device on the heating electrode, where forming the heating electrode further comprises:
forming a first ferromagnetic layer, to be magnetized in a first direction, on the access device
forming a diamagnetic layer on the first ferromagnetic layer; and
forming a second ferromagnetic layer, to be magnetized in a direction opposite to the first direction, on the diamagnetic layer, where the second ferromagnetic layer is formed to contact the variable resistance device.

19. The method of claim 18, wherein forming the heating electrode further comprises:
forming an anti-ferromagnetic layer between the access device and the first ferromagnetic layer.

20. The method of claim 18, wherein the first and second ferromagnetic layers are formed to be magnetized in a horizontal direction.

21. The method of claim 19, wherein the first and second ferromagnetic layers are formed to be magnetized in a horizontal direction.

22. The method of claim 18, wherein the first and second ferromagnetic layers are formed to be magnetized in a vertical direction.

23. The method of claim 19, wherein the first and second ferromagnetic layers are formed to be magnetized in a vertical direction.

24. The method of claim 18, wherein the diamagnetic layer includes a metal material.

25. The method of claim 18, wherein the diamagnetic layer includes an insulating material.
